(19) United States
(12) Patent Application Publication
(10) Pub. No.: US 2026/0074666 A1
(43) Pub. Date: Mar. 12, 2026

(54) CURRENT CONVERTER CIRCUIT

(71) Applicant: NXP B.V., Eindhoven (NL)

(72) Inventors: Xin Yang, Eindhoven (NL); Lars Gustaf Jansson, Stockholm (SE)

(21) Appl. No.: 19/313,030

(22) Filed: Aug. 28, 2025

(30) Foreign Application Priority Data
Sep. 10, 2024 (EP) 24199474.8

(51) Int. Cl. H03G 3/30; H03G 1/00

(52) U.S. Cl. CPC H03G 3/3042; H03G 1/0052; H03G 1/007; H03G 2201/103; H03G 2201/307; H03G 2201/504

(57) ABSTRACT

The disclosure relates to a current converter circuit. Example embodiments include a current converter circuit (600) for converting a linear input current (Ictrl_lin) to an exponential output current (Ictrl_sum), the current converter circuit (600) comprising first and second current converters (601, 602), each of which comprises: an input current branch (603₁, 603₂) with an input current source (604₁, 604₂) connected in series with a tuning voltage circuit (605₁, 605₂) and a tuning resistor (606₁, 606₂) between a supply voltage line (607) and a common voltage line (608); and an output current branch (609₁, 609₂) with an output transistor (610₁, 610₂) having a collector connected to an output node (611₁, 611₂), a emitter connected to the common voltage line (608) and a base connected to the tuning voltage circuit (605₁, 605₂), wherein the output nodes (611₁, 611₂) of the first and second current converters (601, 602) are connected to a summing output node (612) of the current converter circuit (600)

### FIELD

The disclosure relates to a current converter circuit.

### BACKGROUND

A variable gain amplifier (VGA) requires a control input for defining a gain of the VGA. In applications such as RF transmitters, a VGA is a component in the transmission line between a RF signal input and an RF antenna output. Gain control of the VGA may require a signal that varies exponentially, driven by a linearly varying gain control signal. A converter is therefore required in such cases that converts a linearly varying input control signal to an exponentially varying output control signal. A current converter circuit may form part of circuit for providing such gain control, in which a linearly varying input current is converted to an exponentially varying output current, which is then converted to a gain control voltage signal provided to the VGA. A problem with existing current converter circuits for providing such control is being able to maintain a uniformly varying output over typically several orders of magnitude.

### SUMMARY

According to a first aspect there is provided a current converter circuit for converting a linear input current to an exponential output current, the current converter circuit comprising first and second current converters, each of which comprises:
an input current branch with an input current source connected in series with a tuning voltage circuit and a tuning resistor between a supply voltage line and a common voltage line; and
an output current branch with an output transistor having a collector connected to an output node, an emitter connected to the common voltage line and a base connected to the tuning voltage circuit,
wherein the output nodes of the first and second current converters are connected to a summing output node of the current converter circuit.

The tuning voltage circuit of each of the first and second current converters optionally comprises a diode-connected NPN transistor and a diode-connected MOS transistor.

In some examples the diode-connected NPN transistor is an input transistor having a collector connected to the input current source, an emitter connected to the tuning resistor and a base connected to the base of the output transistor.

The diode connected MOS transistor may be a tuning transistor having a gate connected to the input current source, a source connected to the base of the input and output transistors and a drain connected to the supply voltage line.

The base of the output transistor of each of the first and second current converters may be connected to the tuning voltage circuit via the tuning resistor.

In some examples the tuning voltage circuit of each of the first and second current converters comprises a voltage regulator and a tuning transistor, the voltage regulator having a first input for receiving a tuning voltage signal and a second input connected to a gate of the tuning transistor, an output of the voltage regulator connected to a drain of the tuning transistor and a source of the tuning transistor connected to the common voltage line.

The tuning resistor of each of the current converters may be adjustable.

In some examples, the input current source of each of the first and second current converters comprises a current source transistor having a gate connected to an input node of the current converter circuit, a source connected to the supply voltage line and a drain connected to the tuning voltage circuit.

According to a second aspect there is provided a gain control circuit for a variable gain amplifier, comprising:
a current converter circuit according to the first aspect;
a current to voltage converter circuit connected to the output current branch and configured to convert an output current through the output current branch to a differential output voltage signal.

In some examples the current to voltage converter circuit is a complementary differential amplifier configured to convert a single-ended current from the output current branch to the differential output voltage signal.

According to a third aspect there is provided a variable gain RF amplifier comprising:
an RF input;
an RF output;
a Gilbert Cell amplifier connected between the RF input and RF output; and
a gain control circuit according to the second aspect, wherein the differential output signal is connected to control a gain of the Gilbert Cell amplifier.

According to a fourth aspect there is provided a transmitter comprising a plurality of channels, each channel comprising a variable gain RF amplifier according to the third aspect, a power amplifier and an antenna.

Each of the plurality of channels may comprise a coarse phase shifter and a fine phase shifter, the variable gain RF amplifier, coarse phase shifter and fine phase shifter being connected in line to provide an amplified phase shifted signal to the power amplifier.

These and other aspects of the invention will be apparent from, and elucidated with reference to, the embodiments described hereinafter.

### BRIEF DESCRIPTION OF DRAWINGS

Embodiments will be described, by way of example only, with reference to the drawings, in which:

FIG. 1 is a schematic diagram of an example 2-channel transmitter for an analog beamforming circuit;

FIG. 2 is a schematic diagram of an example variable gain amplifier circuit;

FIG. 3 is a block diagram illustrating an example arrangement for the gain and phase control circuit of FIG. 2;

FIG. 4 is a schematic circuit diagram of an example current to current (I2I) and current to voltage (I2V) circuit for the arrangement of FIG. 3;

FIG. 5 is an example plot of VGA gain as a function of input gain control code using the circuit of FIG. 4;

FIG. 6 is a schematic circuit diagram of an example I2I circuit;

FIGS. 7a-7d are example plots of output current as a function of input current for the circuit of FIG. 6;

FIG. 8 is an example plot of VGA gain as a function of input gain control code using the circuit of FIG. 6;

FIG. 9 is an example plot of gain step per unit code change as a function of input gain control code using the circuit of FIG. 6;

FIG. 10 is a schematic circuit diagram of an example I2I circuit and a corresponding representation of the I2I circuit;

FIG. 11a is a plot of output current as a function of input current for an example I2I circuit with a fixed tuning voltage and different tuning resistor values;

FIG. 11b is a plot of output current as a function of input current for an example I2I circuit with a fixed tuning resistor and different tuning voltages;

FIG. 12a is a plot of output current as a function of input current for an example I2I circuit with a fixed tuning voltage and different tuning resistor values;

FIG. 12b is a plot of a derivative of output current as a function of tuning resistance with a fixed tuning voltage;

FIG. 12c is a plot of output current as a function of input current for an example I2I circuit with a first tuning resistance and different tuning voltages;

FIG. 12d is a plot of a derivative of output current as a function of tuning voltage with a fixed tuning resistance;

FIG. 13 is a schematic simplified circuit diagram of an example I2I circuit;

FIG. 14 is a schematic circuit diagram of an example implementation of the circuit of FIG. 13; and

FIG. 15 is a schematic circuit diagram of an example alternative I2I circuit comprising multiple parallel current to current converter circuits.

It should be noted that the Figures are diagrammatic and not drawn to scale. Relative dimensions and proportions of parts of these Figures have been shown exaggerated or reduced in size, for the sake of clarity and convenience in the drawings. The same reference signs are generally used to refer to corresponding or similar feature in modified and different embodiments.

### DETAILED DESCRIPTION OF EMBODIMENTS

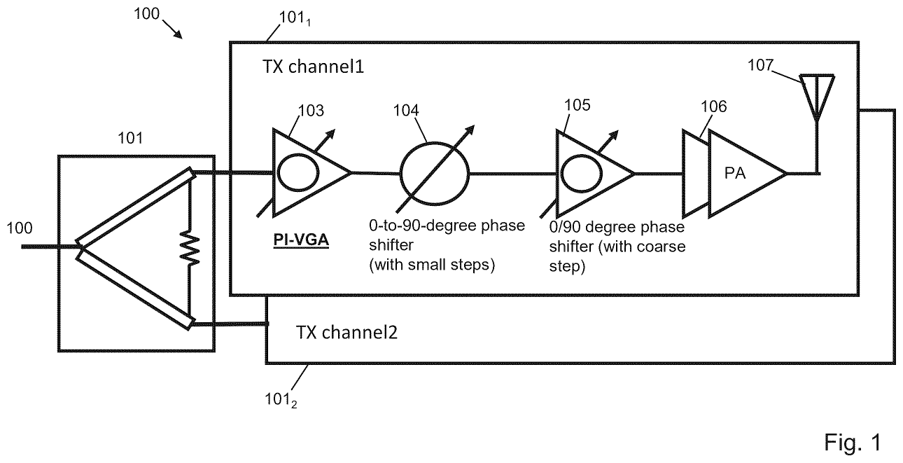

An example of a transmitter (TX) line 100 comprising two channels 101₁, 101₂ is illustrated in FIG. 1, which represents various components of an analog beamforming integrated circuit (IC). Each channel 101₁, 101₂ comprises a VGA, in this example a phase-inverting VGA (PI-VGA) 103, a fine 0 to 90 degree phase shifter 104, a coarse 0/90 degree phase shifter 105 and a power amplifier (PA) 106, which outputs an amplified RF signal to an antenna 107. The fine 0 to 90 degree phase shifter 104 applies a phase shift in relatively small steps, for example in steps covering 0, 5.625, 11.24, . . . 84.375, and 90 degrees, and may be implemented with a passive reflective-type phase shifter (RTPS). The coarse 0/90 degree phase shifter 105 applies a phase shift in larger steps of 90° and may be implemented by passive or active components. In combination, the phase shifters 104, 105 apply a desired phase shift to the signal provided to the power amplifier 106. For an application such as an analog beamformer or a phased array system, control of the phase of the output signal over a full 360° is required for each channel. For this, the PI-VGA 103 is used to achieve a desired 0/180° phase shift in combination with the coarse 0/90° phase shifter 105 and the fine 0-to-90° phase shifter.

The PI-VGA 103 comprises a VGA with a linear control input that controls a gain of the VGA in dB. The PI-VGA 103 has two functions: tapering gain control and 0/180 degree phase shifting. For tapering gain control, the gain required in dB is ideally proportional to the input linear control code.

The order in which the components 103, 104, 105 is provided in each channel 101₁, 101₂ may vary from that shown in FIG. 1, for example by applying one or both of the phase shifters 104, 105 before the PI-VGA 103. The PI-VGA 103 of the type described herein may also be used in other types of transmitter lines and in other applications such as in a receiver line or IQ modulator.

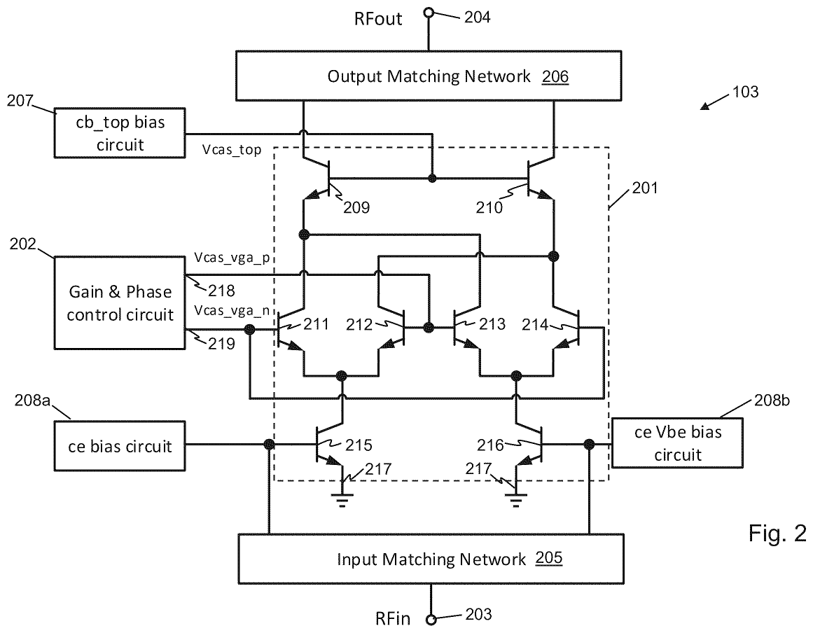

FIG. 2 illustrates an example PI-VGA unit cell core 103 of the type described above in relation to FIG. 1. An analog bias circuit for the PI-VGA is not shown. The PI-VGA 103 comprises a classical Gilbert Cell 201 with a top common-base (current re-used) buffer. The top common-base buffer significantly improves the RF performance in both the Gain-to-Phase error and linearity. A gain and phase control bias circuit 202 provides a differential gain control signal Vcas_vga_p, Vcas_vga_n to the Gilbert cell.

The VGA 103 comprises an RF input 203 and an RF output 204. An input matching network 205 is connected between the RF input 202 and the Gilbert cell amplifier 201. An output matching network 206 is connected between the Gilbert cell amplifier 201 and the RF output 204.

Bias circuits 207, 208a, 208b apply bias voltage signals to various transistors making up the Gilbert cell 201, which in this example are bipolar junction transistors. A common base top bias circuit 207 applies a bias voltage to the base of each of first and second transistors 209, 210. An emitter of each of the first and second transistors 209, 210 is connected to the output matching network 206. A source of the first transistor 209 is connected to an emitter of a third transistor 211 and a fifth transistor. A source of the second transistor 210 is connected to an emitter of a fourth transistor 212 and a sixth transistor 214. A first output 218 of the gain and phase control circuit 202, providing Vcas_vga_p, is connected to a base of the fourth transistor 212 and fifth transistor 213. A second output 219 of the gain and phase control circuit 202, providing Vcas_vga_n, is connected to a base of the third transistor 211 and sixth transistor 214. Sources of the third transistor 211 and fourth transistor 212 are connected to an emitter of a seventh transistor 215. Sources of the fifth transistor 213 and sixth transistor 214 are connected to an emitter of an eight transistor 217. A base of the seventh transistor is connected to a first common emitter bias circuit 208a and to the input matching network 205. A base of the eight transistor is connected to a second common emitter bias circuit 208b and to the input matching network 205. Sources of the seventh and eighth transistors 215, 216 are connected to a common voltage rail 217 (e.g. a ground connection).

When the gain of VGA 103 is high, the differential bias voltage applied by Vcas_vga_p and Vcas_vga_n is high (for example a 200 mV voltage difference). To decrease the gain of the VGA, this voltage difference is decreased. The physical behaviour of the Gilbert cell VGA 103 is that the gain of the VGA 103 in dB is proportional to the bias voltage difference in dB, i.e. log(Gain)∝ log(Vdiff), where in this case Vdiff=Vcas_vga_p−Vcas_vga_n. What is required is for the gain of the VGA 103 in dB to be proportional to the linear control current in magnitude, i.e. log(Gain)∝Ictrl_lin. The bias voltage difference therefore needs to be in magnitude exponential in relation to the control current in magnitude, i.e. Vdiff∝exp(Ictrl_lin).

Phase inverting the output of the VGA 103 is achieved by swapping the bias voltage of Vcas_vga_p and Vcas_vga_n. In one phase setting, Vcas_vga_p>Vcas_vga_n, which can be inverted to achieve a 180-degree phase shift, i.e. swapping the voltages to make Vcas_vga_p<Vcas_vga_n.

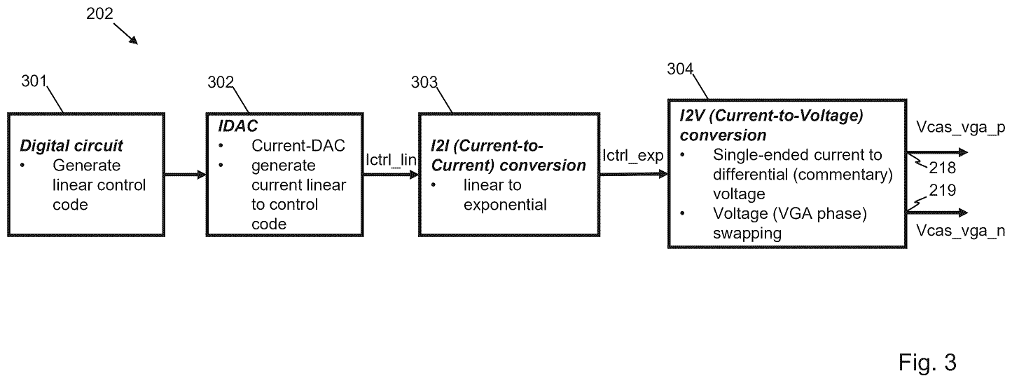

FIG. 3 illustrates a schematic block diagram of an example gain and phase control circuit 202 to generate the differential bias voltage: Vcas_vga_p and Vcas_vga_n. The circuit 202 comprises a digital circuit 301, which generates a digital linearly varying control code. This control code is provided to a digital to analog converter 302, which converts the digital control code to a linearly varying control current, Ictrl_lin. This control current is provided to a current-to-current (I2I) converter 303, which converts the linearly varying control current Ictrl_lin to an exponentially varying control current Ictrl_exp. The exponentially varying control current Ictrl_exp is provided to a current-to-voltage (I2V) converter 304, which outputs the differential bias voltage Vcas_vga_p and Vcas_vga_n at first and second outputs 218, 219.

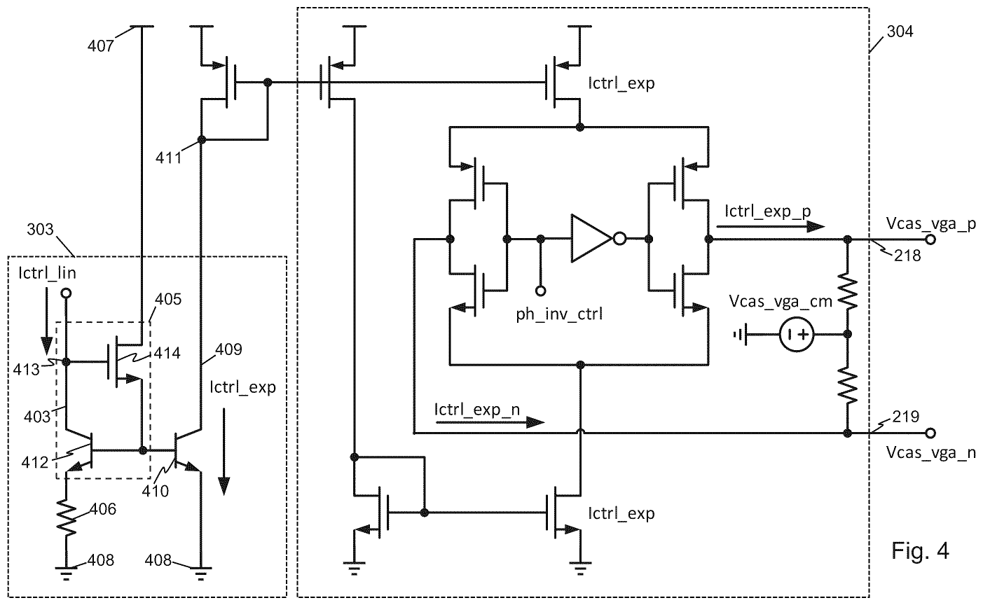

FIG. 4 illustrates an example of the I2I and I2V converter circuits 303, 304 of FIG. 3. The linearly varying control current Ictrl_lin (which may include a fixed current component I_fix) is provided to an input current branch 403 of the I2I converter circuit 303, which comprises a tuning voltage circuit 405 and a tuning resistor 406 between a supply voltage line 407 and a common voltage line 408. An output current branch 409 of the I2I converter circuit 303 comprises an output transistor 410 having a drain connected to an output node 411, a source connected to the common voltage line 408 and a base connected to the tuning voltage circuit 405.

The tuning voltage circuit 405 in this example comprises an input transistor 412 having an emitter connected to an input node 413, a source connected to the tuning resistor 406 and a base connected to the base of the output transistor 410. The input and output transistors 412, 410 are in this example bipolar junction transistors. The tuning voltage circuit 405 also comprises a tuning transistor 414 having a gate connected to the input node 413, a source connected to the base of the input and output transistors 412, 410 and a drain connected to the supply voltage line 407. The tuning transistor 414 in this example is a FET.

The linearly varying control current Ictrl_lin is provided by the current DAC 302, which generates an output current proportional to the input gain code, and therefore varies in equal steps as the input gain code varies. A fixed current source I_fix may provide a current offset to the linearly varying control current, such that Ictrl_lin=I_fix+I_step*Gain_code, where Gain_code is the input gain code and I_step is the unit step change in current for a single bit change in the input gain code.

The I2V converter circuit 304 is a complementary differential amplifier that converts the single-ended exponentially varying output current Ictrl_exp from the I2I converter circuit 303 to a differential voltage output Vcas_vga_p, Vcas_vga_n at the first and second outputs 218, 219. A phase inverting input 415 allows a phase inverting control signal ph_inv_ctrl to switch the outputs to invert the phase of the Gilbert cell amplifier 201. An example of a complementary differential amplifier for use as the I2V converter circuit 304 is disclosed by M. Bazes, “Two novel fully complementary self-biased CMOS differential amplifiers,” in IEEE Journal of Solid-State Circuits, vol. 26, no. 2, pp. 165-168, February 1991, doi: 10.1109/4.68134.

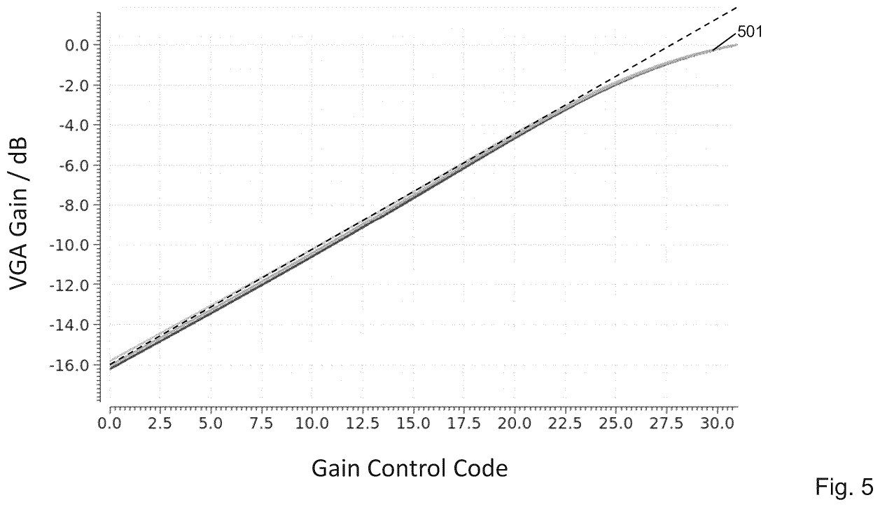

FIG. 5 is a plot of VGA gain as a function of gain control code, with the gain varying from −16 dB to 0 dB as the gain control code varies from 0 to 31 (i.e. over a 5 bit range). It can be seen from this that the VGA gain 501 departs from linearity when the gain control code is over 24, indicating that the VGA gain step is no longer constant. In order to maintain linear control, the maximum gain control code can be set to 24, meaning that the VGA is working with a back-off of in this example around 2 dB. It would be advantageous to be able to operate the VGA in a linear gain control region beyond this range, which benefits linearity and noise of the VGA.

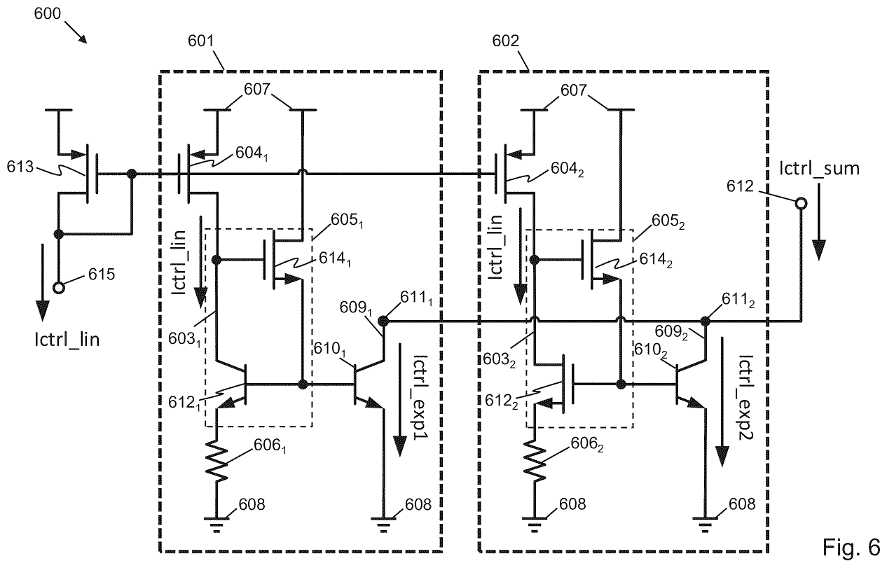

FIG. 6 illustrates an example current converter circuit 600 to replace the current converter circuit 303 of FIG. 4 that solves the above problem. The current converter circuit 600 comprises first and second current converters 601, 602, each of which is similar to the single current converter circuit 303 of FIG. 4. Each current converter 601, 602 comprises an input current branch 603₁, 603₂ and an output current branch 609₁, 609₂, with an output node 611₁, 611₂ of the first and second current converters 601, 602 connected to a summing output node 612 of the current converter circuit 600.

The input current branch 603₁, 603₂ of each current converter 601, 602 comprises an input current source 604₁, 604₂ connected in series with a tuning voltage circuit 605₁, 605₂ and a tuning resistor 606₁, 606₂ between a supply voltage line 607 and a common voltage line 608 (e.g. a ground connection). The output current branch 609₁, 609₂ comprises an output transistor 610₁, 610₂ having a common connection connected to an output node 611₁, a source connected to the common voltage line 608 and a base connected to the tuning voltage circuit 605₁, 605₂.

The tuning voltage circuit 605₁, 605₂ of each of the first and second current converters 601, 602 in this example comprises an input transistor 612₁, 612₂ in the form of a diode-connected NPN transistor having a common connection connected to the input current source 604₁, 604₂, an emitter connected to the tuning resistor 606₁, 606₂ and a base connected to the base of the output transistor 610₁, 610₂. The input and output transistors 612₁, 612₂, 610₁, 610₂ are in this example NPN bipolar junction transistors. The tuning voltage circuit 605₁, 605₂ also comprises a diode connected MOS transistor in the form of a tuning transistor 614₁, 614₂ having a gate connected to the input current source 604₁, 604₂, a source connected to the base of the input and output transistors 612₁, 612₂, 610₁, 610₂ and a drain connected to the supply voltage line 607. The tuning transistors 614₁, 614₂ are in this example NFETs. In alternative examples, the tuning transistors 614₁, 614₂ may be replaced by NPN BJTs or other types of transistors.

The current source 604₁, 604₂ in each of the first and second current converter 601, 602 comprise a current source transistor having a gate connected to an input node 615 of the current converter circuit 600, a source connected to the supply voltage line 607 and a drain connected to the tuning voltage circuit 605₁, 605₂, i.e. in this example to the gate of the tuning transistor 614₁, 614₂ and the common connection of the input transistor 612₁, 612₂. The current source transistors 604₁, 604₂ are in this example PFETs. In alternative examples, the current source transistors 604₁, 604₂ may be replaced by PNP BJTs or other types of transistors.

The linear input current Ictrl_lin is provided to each input current source 604₁, 604₂ via a common input current source transistor 613, which in this example is a PFET having a source connected to the supply voltage line 607, a gate connected to the gate of the input current source 604₁, 604₂ of each of the first and second current converters 601, 602 and with the drain and gate connected together and to the current input node 615.

Adding an extra I2I converter 602 in parallel with the first converter 601 and summing the output currents to provide a summed output current Ictrl_sum, i.e. such that Ictrl_sum=Ictrl_exp1+Ictrlexp2, has the effect of extending the range of the current converter before the output current Ictrl_sum departs from linearity on a plot of gain in dB as a function of linear input current.

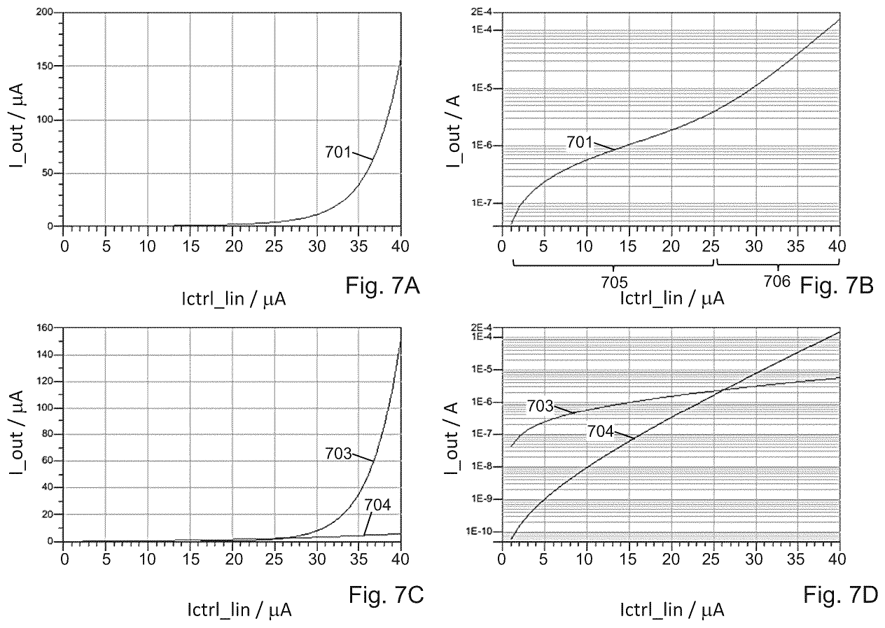

FIGS. 7a-7d illustrate how the output current I_out (in μA) varies as a function of linear input current Ictrl_lin, with FIGS. 7a and 7b showing a summed current output 701 in linear and log scales respectively and FIGS. 7c and 7d the separate current components Ictrl_exp1 703 and Ictrl_exp2 704 in linear and log scales respectively as a function of Ictrl_lin. As shown in FIG. 7b, over a lower first range 705, in this case from 0 to around 25 μA, the first output current Ictrl_exp1 703 dominates the summed output current, while in a higher second range 706, in this case above around 25 μA, the second output current Ictrl_exp2 704 dominates the summed output current. These ranges correspond to VGA low and high gain settings respectively.

For the input control current Ictrl_in above around 15 μA, both Ictrl_exp1 and Ictrl_exp2 vary exponentially in relation to the linear input current Ictrl_lin. The relationship between the output currents Ictrl_exp1 and Ictrl_exp2 (in log) in this case have difference slopes. In this example, when Ictrl_lin<25 μA, the output summed current Ictrl_sum is dominated by Ictrl_exp1, and when Ictrl_lin>25 μA, the summed output current Ictrl_sum is dominated by Ictrl_exp2.

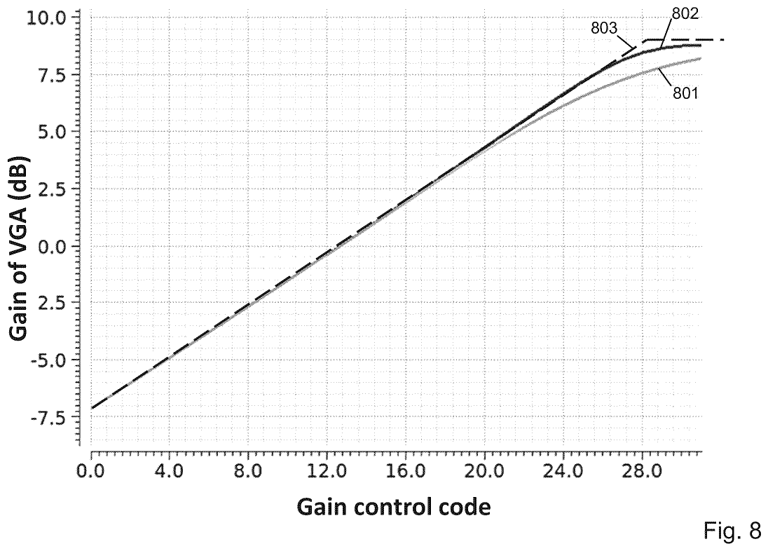

FIG. 8 illustrates an example plot of VGA gain as a function of gain control code for the VGA provided with a summed current Ictrl_sum from a current converter of the type described above in relation to the example in FIG. 6 compared to the VGA provided with a current from a converter of the previous type described above in relation to the example in FIG. 4. The gain 801 from the previous type of converter shows a departure from linearity above an input code of around 20, while the gain 802 from the summed current converter circuit shows an increased linear region up to around 26. This demonstrates a wider VGA linear gain control range for the summed current output converter circuit, which is closer to the ideal case 803.

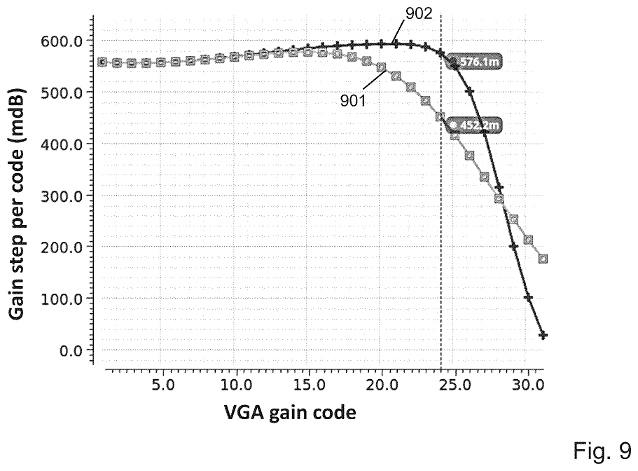

FIG. 9 illustrates the difference in performance by plotting the gain step per unit code as a function of VGA gain code, showing that the gain step 901 for the previous converter drops off at a lower gain code compared to the gain step 902 for the summed current converter. This shows that the gain step drops by around 0.1-dB (from 0.55-dB to 0.45-dB) with a gain code of 24 for the previous current converter, while the gain step is still constant with the summed current converter.

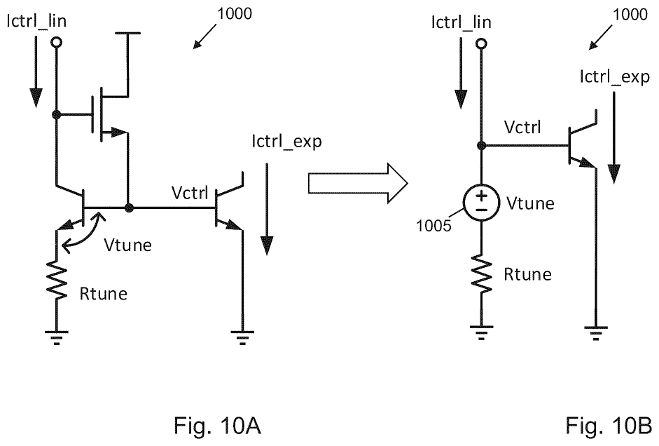

FIGS. 10a and 10b illustrate an example I2I circuit 1000 to explain the operation principles of the circuit and indicate alternative example arrangements. The circuit diagram in FIG. 10a indicates the components of the example current converter circuits in FIGS. 4 and 6. This can be simplified to the schematic circuit in FIG. 10b, in which the tuning voltage circuit 1005 is indicated as a single component.

Applying the basic formula for an NPN transistor

$${I}_{C} \approx {I}_{E n} = {I}_{S} \times {e}^{\frac{{V}_{B E}}{{V}_{T}}} ,$$

the output current Ictrl_exp can be expressed as

$${I}_{ctrl \_ exp} \approx {I}_{S} \times {e}^{\frac{{I}_{ctrl \_ lin} \times {R}_{tune} + {V}_{tune}}{{V}_{T}}} .$$

The output current thereby varies exponentially as a function of the linear input current Ictrl_lin, and can be tuned by the tuning resistor value Rtune and tuning voltage valve Vtune.

Following the above calculation, taking the natural logarithm for both sides of the equation above results in:

$$ln ( {I}_{ctrl \_ exp} ) \approx ln ( {I}_{S} ) + \frac{{I}_{{ctrl}_{l i n}} \times {R}_{t u n e} + {V}_{t u n e}}{{V}_{T}}$$

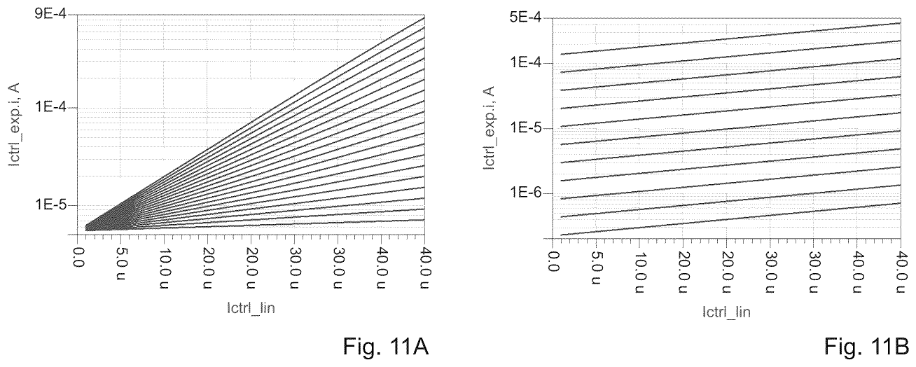

The logarithm of the output current Ictrl_exp should therefore be proportional to the tuning resistor value Rtune and to the tuning voltage Vtune. The relationship between Ictrl_exp in log scale as a function of Ictrl_lin in linear scale is shown in FIGS. 11a and 11b, with FIG. 11a showing different relationships for different Rtune values with a fixed Vtune value and FIG. 11b showing different relationships for different Vtune values with a fixed Rtune value. These illustrate that the slope of the curve for each current converter can be adjusted by changing Rtune, and the level of the curve can be shifted up or down by changing Vtune.

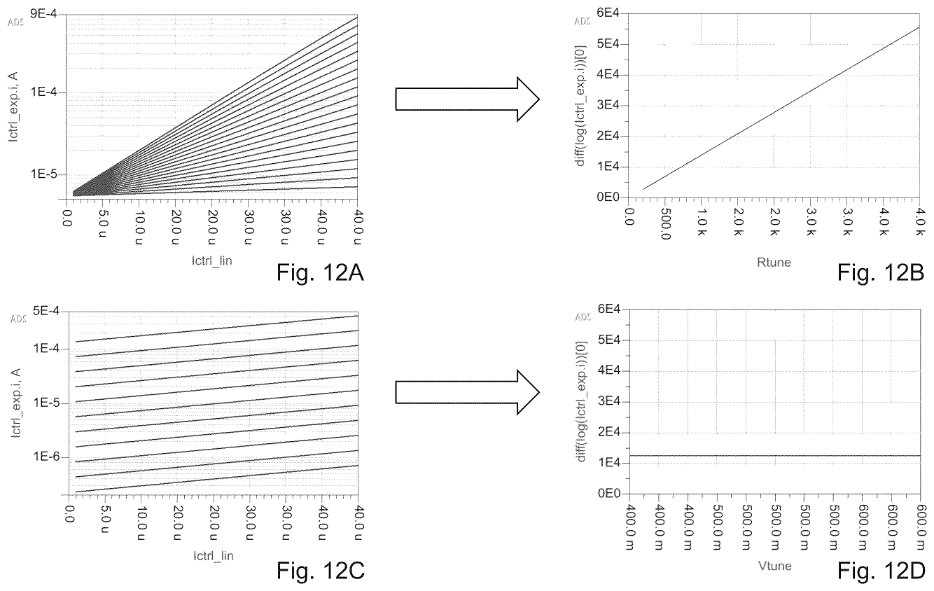

FIGS. 12a-12d further illustrate the effect of adjusting Vtune and Rtune. FIG. 12a shows the different relationships with different Rtune values and a fixed Vtune value and FIG. 12b shows the relationship between the derivative of the output current as a function of Rtune, i.e. the slope of the curves in FIG. 12a. FIG. 12c shows the different curves from varying the Rtune value while keeping Vtune fixed and FIG. 12d shows that the derivative of the output current stays constant over the range of Vtune values. As a result, a design procedure for optimising the current converter circuit can involve firstly tuning Rtune for the desired slope and then tuning Vtune for the desired offset value.

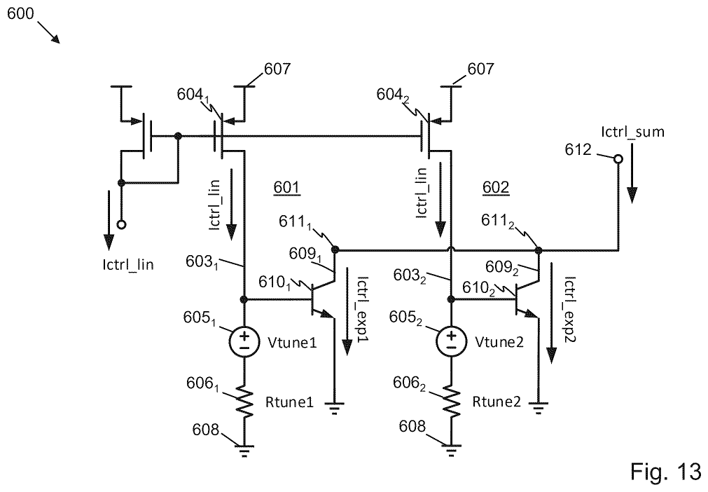

Based on the analysis above, the operational principle of the current converter in FIG. 6 can be simplified to that illustrated in FIG. 13, in which the same reference signs as in FIG. 6 are used to indicate corresponding components. In a practical design, a diode-connected NPN transistor and a diode-connected MOS transistor, as illustrated in FIG. 6, can be used to generated different voltage drops Vtune1 and Vtune2, and different resistors Rtune1 and Rtune2 can be used to control the slopes of the exponentially varying output control current Ictrl_exp (in log scale) as a function of the linearly varying input control current Ictrl_lin.

In an ideal case, the values of Vtune1 and Vtune2 should be independent of the linear input control current Ictrl_lin, which is not completely accurate with a diode-connected transistor. However, since the voltage drop across the resistors (Rtune1 and Rtune2) is proportional to Ictrl_lin, the voltage drop across the diodes (Vtune1 and Vtune2) is approximately constant over the variation in Ictrl_lin.

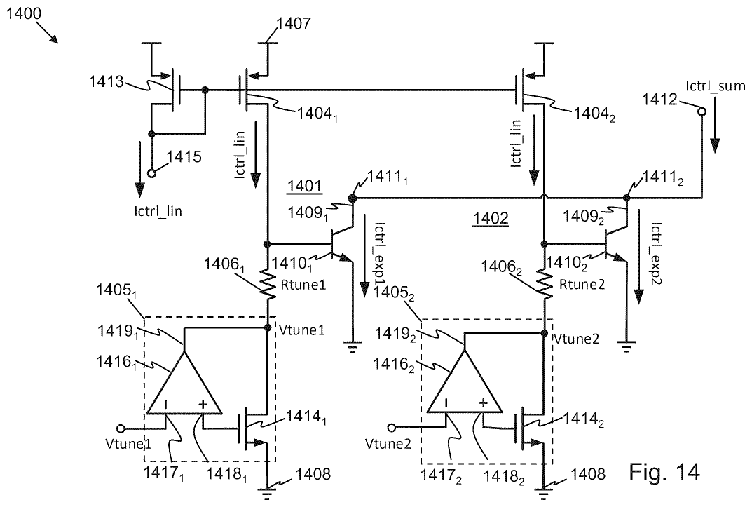

In an alternative arrangement, FIG. 14 illustrates an example of a current converter circuit 1400 in which the tuning voltage circuit 1405₁, 1405₂ in each of the first and second current converters 1401, 1402 comprises an LDO (low drop out) voltage regulator 1416₁, 1416₂ and a tuning transistor 1414₁, 1414₂ to buffer Vtune1 and Vtune2 values that are provided as inputs to the first and second current converters 1401, 1402. This makes the tuning voltages Vtune1, Vtune2 independent of the input linear control current Ictrl_lin. The voltage regulators 1416₁, 1416₂ each have a first input 1417₁, 1417₂ for receiving a tuning voltage signal Vtune1, Vtune2 and a second input 14181, 14182 connected to a gate of the tuning transistor 1414₁, 1414₂. An output 1419₁, 1419₂ of the voltage regulator 1416₁, 1416₂ is connected to a drain of the tuning transistor 1414₁, 1414₂. A source of the tuning transistor 1414₁, 1414₂ is connected to the common voltage line 1408. Other components of the first and second current converters 1401, 1402 of the current converter circuit 1400, together with their connections, are similar to corresponding components of the current converter circuit 600 described above, including the output current branch 1409₁, 1409₂, output transistor 1410₁, 1410₂, output node 1411₁, 1411₂, summing output node 1412, input current source transistor 1413 and input node 1415.

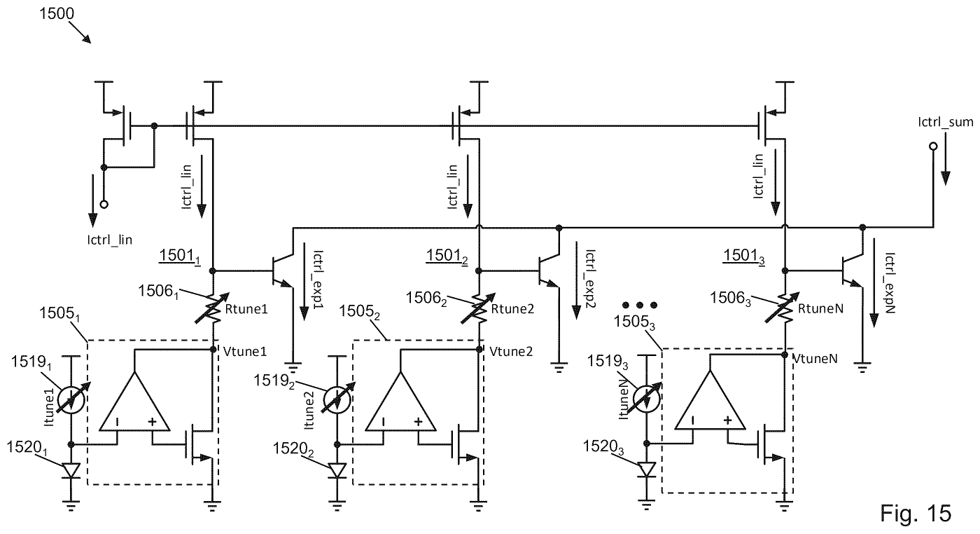

The number of current converters making up the current converter circuit is not necessarily limited to two and in some examples the current converter circuit may have three or more current converters arranged in parallel. FIG. 15 illustrates an example alternative current converter circuit 1500 with three (or more) current converters 1501₁, 1501₂, 1501₃. Each current converter may be similar to the current converters 1401, 1402 described above in relation to FIG. 14, or may be similar to the current converters 601, 602 described above in relation to FIG. 6. The tuning voltage circuits 1505₁, 1505₂, 1505₃ in the illustrated example are provided with a tuning voltage signal from a variable current source 1519₁, 1519₂, 1519₃ in series with a diode 1520₁, 1520₂, 1520₃. Adjusting the current itune1, itune2, itune3 through the current sources 1519₁, 1519₂, 1519₃ adjusts the tuning voltage Vtune1, Vtune2, Vtune3 applied to the tuning voltage circuits 1505₁, 1505₂, 1505₃. The diodes may be implemented using diode-connected transistors, which may for example be bipolar or MOS transistors.

Other components of each of the current converters 1501₁₋₃, together with their relative connections, may be similar to those in the examples described above in FIGS. 6 and 14.

The tuning resistors 1506₁₋₃ may themselves be tuneable, such that the tuning resistance values Rtune1, Rtune2, Rtune3 are adjustable, thereby allowing the current converter circuit to be reconfigurable to adjust the slope of each portion of the gain range.

From reading the present disclosure, other variations and modifications will be apparent to the skilled person. Such variations and modifications may involve equivalent and other features which are already known in the art of current converters, gain control circuits and/or variable gain amplifiers, and which may be used instead of, or in addition to, features already described herein.

Although the appended claims are directed to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable sub-combination. The applicant hereby gives notice that new claims may be formulated to such features and/or combinations of such features during the prosecution of the present application or of any further application derived therefrom.

For the sake of completeness it is also stated that the term “comprising” does not exclude other elements or steps, the term “a” or “an” does not exclude a plurality, a single processor or other unit may fulfil the functions of several means recited in the claims and reference signs in the claims shall not be construed as limiting the scope of the claims.

1. A current converter circuit for converting a linear input current to an exponential output current, the current converter circuit comprising first and second current converters, each of which comprises:
an input current branch with an input current source connected in series with a tuning voltage circuit and a tuning resistor between a supply voltage line and a common voltage line; and
an output current branch with an output transistor having a collector connected to an output node an emitter connected to the common voltage line and a base connected to the tuning voltage circuit,
wherein the output nodes of the first and second current converters are connected to a summing output node of the current converter circuit.

2. The current converter circuit of claim 1, wherein the tuning voltage circuit of each of the first and second current converters comprises a diode-connected NPN transistor and a diode-connected MOS transistor.

3. The current converter circuit of claim 2, wherein the diode-connected NPN transistor is an input transistor, having a collector connected to the input current source, an emitter connected to the tuning resistor and a base connected to the base of the output transistor.

4. The current converter circuit of claim 3, wherein the diode connected MOS transistor is a tuning transistor having a gate connected to the input current source, a source connected to the base of the input and output transistors and a drain connected to the supply voltage line.

5. The current converter circuit of claim 1, wherein the base of the output transistor of each of the first and second current converters is connected to the tuning voltage circuit via the tuning resistor.

6. The current converter circuit of claim 5, wherein the tuning voltage circuit of each of the first and second current converters comprises a voltage regulator and a tuning transistor, the voltage regulator having a first input for receiving a tuning voltage signal and a second input connected to a gate of the tuning transistor, an output of the voltage regulator connected to a drain of the tuning transistor and a source of the tuning transistor connected to the common voltage line.

7. The current converter circuit of claim 1, wherein the tuning resistor of each of the current converters is adjustable.

8. The current converter circuit of claim 1, wherein the input current source of each of the first and second current converters comprises a current source transistor having a gate connected to an input node of the current converter circuit, a source connected to the supply voltage line and a drain connected to the tuning voltage circuit.

9. A gain control circuit for a variable gain amplifier, comprising:
a current converter circuit according to claim 1;
a current to voltage converter circuit connected to the output current branch and configured to convert an output current through the output current branch to a differential output voltage signal.

10. The gain control circuit of claim 9, wherein the current to voltage converter circuit is a complementary differential amplifier configured to convert a single-ended current from the output current branch to the differential output voltage signal.

11. A variable gain RF amplifier comprising:
an RF input;
an RF output;
a Gilbert Cell amplifier connected between the RF input and RF output; and
a gain control circuit according to claim 9, wherein the differential output signal is connected to control a gain of the Gilbert Cell amplifier.

12. A transmitter comprising a plurality of channels, each channel comprising a variable gain RF amplifier according to claim 11, a power amplifier and an antenna.

13. The transmitter of claim 12, wherein each of the plurality of channels comprises a coarse phase shifter and a fine phase shifter, the variable gain RF amplifier, coarse phase shifter and fine phase shifter connected in line to provide an amplified phase shifted signal to the power amplifier.

14. The gain control circuit of claim 9, wherein the tuning voltage circuit of each of the first and second current converters comprises a diode-connected NPN transistor and a diode-connected MOS transistor.

15. The gain control circuit of claim 14, wherein the diode-connected NPN transistor is an input transistor having a collector connected to the input current source, an emitter connected to the tuning resistor and a base connected to the base of the output transistor.

16. The gain control circuit of claim 9, wherein the base of the output transistor of each of the first and second current converters is connected to the tuning voltage circuit via the tuning resistor.

17. The gain control circuit of claim 16, wherein the tuning voltage circuit of each of the first and second current converters comprises a voltage regulator and a tuning transistor, the voltage regulator having a first input for receiving a tuning voltage signal and a second input connected to a gate of the tuning transistor, an output of the voltage regulator connected to a drain of the tuning transistor and a source of the tuning transistor connected to the common voltage line.

18. The gain control circuit of claim 17, wherein the tuning resistor of each of the current converters is adjustable.

19. The gain control circuit of claim 9, wherein the input current source of each of the first and second current converters comprises a current source transistor having a gate connected to an input node of the current converter circuit, a source connected to the supply voltage line and a drain connected to the tuning voltage circuit.

20. The gain control circuit of claim 9, wherein the current to voltage converter circuit is a complementary differential amplifier configured to convert a single-ended current from the output current branch to the differential output voltage signal.
